(19) United States
(12) Patent Application Publication
(10) Pub. No.: US 2011/0232718 A1
(43) Pub. Date: Sep. 29, 2011

(54) SOLAR COLLECTOR

(76) Inventor: KHURRAM K. NAWAB, ROCKFORD, IL (US)

(21) Appl. No.: 12/623,438

(22) Filed: Nov. 22, 2009

Related U.S. Application Data
(60) Provisional application No. 61/117,231, filed on Nov. 23, 2008.

(51) Int. Cl. H01L 31/052

(52) U.S. Cl. 136/246

(57) ABSTRACT

A solar collector with reflective composite sheets consisting of a solid thermoplastic core between an outer aluminum skin. The reflective sheets are secured together with stiffeners formed from the same reflective composite sheet material. The sheets may be connected in modules for securing to longitudinal supports to establish the solar energy reflective surface of the solar collector.

### STATEMENT REGARDING FEDERALLY SPONSORED RESEARCH OR DEVELOPMENT

Not Applicable.

### FIELD OF THE INVENTION

The present invention relates to solar collectors and reflective aluminum composite sheets for solar collectors.

### BACKGROUND OF THE INVENTION

One type of solar collector uses aluminum sheets, that are coated with a material to establish high surface reflectivity and low absorption of solar energy, and that are held in a desired curvature with a frame support structure. A common frame consists of longitudinal straight supports (e.g., pole supports) and lateral curved supports. Aluminum sheets used in this type of solar collectors are typically about 0.020 inch thick.

When aluminum sheets are used in solar collectors of this type, the aluminum sheets exhibit a “waviness” that can have a detrimental affect on the surface reflectivity and the efficiency of solar energy collection.

This “waviness” and its detrimental affect on efficiency can become significant when large sheets are used, as is common in large solar collectors of a size and type used for purposes other than personal power generation, such as in commercial and large scale research facilities.

To counteract the “waviness,” i.e., to “flatten” the sheets to reduce the surface waviness and conform the reflective surface to the desired curvature, a significant number of rivets are used to secure the sheet to the frame support structure. This significant number of rivets can result in up to ten percent of the reflective surface area of the sheet being obscured by the rivet heads, whereas it is generally desired to reduce the reflective surface area of the sheet obscured by the rivet heads by no more than one percent.

Attempts have been made to form reflective solar panels from aluminum with a foam plastic substrate. However, this arrangement has the same waviness problems noted above, as well as additional drawbacks and disadvantage known in the art.

The present invention addresses the above-identified and other known drawbacks and disadvantages of prior solar collectors.

### SUMMARY OF THE INVENTION

An important objective of the invention is to provide a new and unique solar collector that provides high efficiency solar energy collection.

Additional objectives and advantages of the invention include: reducing the natural tendency for “waviness” of the solar energy reflective sheet when formed to the desired curvature; reducing the number of rivets required to secure the reflective sheets to a supporting framework of a solar collector; and increasing the percentage of the surface area of the reflective sheet that is available for reflecting solar energy.

Briefly, the objectives of the invention are promoted through use of a unique aluminum sheet including an aluminum composite sheet that has a mirror reflective finish on one side and a non-reflective finish on the other side, and that has a reduced natural tendency to develop surface “waviness” when formed into the desired curvature, and thereby reduces the number of rivets required to secure the sheet to a support structure and enhances the reflective surface area and reflectivity efficiency of the sheet.

The sheet consists of two layers aluminum skin sandwiching a solid (non-foam) thermoplastic core. The sheet is formed in a continuous co-extrusion process that mechanically bonds the aluminum skin to the thermoplastic core. The sheet provides exceptional bond and thermal integrity. The sheet is easy to work with and easy to bend into virtually any desired shape or curvature (within the mechanical limits of the material), while providing an even “flatness” (i.e., smooth surface curvature on the reflective surface) and sufficient rigidity to hold its curved or other formed shape. The sheet is light weight and weather proof, and has high thermal values. The sheet is easily machined and formed (e.g., rolled, curved, etc.), can be used in other fabrication processes, and is easily installed onto a supporting structure. The sheet can be prepared for quick delivery to a site at which solar collectors are to be constructed or refitted, including from warehouse stock pre-formed into the desired curvature of the solar collector. The sheet also provides for ease of maintenance of the sheet as well as the entire solar collector.

These and other objectives and advantages of the invention will become more apparent from the following detailed description when taken in conjunction with the accompanying drawings.

### BRIEF DESCRIPTION OF THE DRAWINGS

FIG. 1 is an exploded perspective view of a mirror finish aluminum composite sheet suitable for use in a solar collector in accordance with the invention.

FIG. 2 is a perspective view of the mirror finish aluminum composite sheet in its flat condition, ready for forming for use in a solar collector.

FIG. 3 is a perspective view of the back side of the sheet shown in FIG. 2 formed into a desired curvature, a lateral joining stiffener along one of the curved edges of the sheet, and a center joining stiffener along one of the straight edges of the sheet.

FIG. 4 is a perspective view of the front side of the formed sheet shown in FIG. 3.

FIG. 5 is a perspective view of the back side of the formed sheet shown in FIG. 3 with joining stiffeners along both curved edges of the sheet, and ready for securing a second formed sheet thereto both above and below the sheet shown.

FIG. 6 is a perspective view of the curved lateral joining stiffener.

FIG. 7 is a perspective view of the straight center joining stiffener.

FIG. 8 is a back perspective view of six sheets formed into a desired curvature and joined together in sets of three sheets to establish opposite sides of a module in relative position to be joined together and/or secure to the frame support structure of a solar collector.

FIG. 9 is a front perspective view of the aluminum composite sheets and module shown in FIG. 8.

FIG. 10 is a perspective view of curved sheets connected together into modules for use in a parabola-shaped mirror solar collector, similar to the view thereof shown in FIG. 9.

FIG. 11 is a perspective view of a dish-shaped mirror solar collector utilizing formed reflective sheets of the invention.

FIG. 12 is a perspective view of a cone-shaped mirror solar collector utilizing formed reflective sheets of the invention.

FIG. 13 shows a perspective view of the reflective aluminum composite sheet used in the cone-shaped solar collector, with connector strips in place on the edge of the sheet.

FIG. 14 shows an alternate perspective view of the reflective aluminum composite sheet used in the cone-shaped solar collector, with connector strips in place on the edge of the sheet.

FIG. 15 shows another alternate perspective view of the reflective aluminum composite sheet used in the cone-shaped solar collector, with connector strips in place on the edge of the sheet.

FIG. 16 shows another alternate perspective view of the reflective aluminum composite sheet used in the cone-shaped solar collector, without the connector strips on the edge of the sheet.

FIG. 17 shows another alternate perspective view of the reflective aluminum composite sheet used in the cone-shaped solar collector, without the connector strips on the edge of the sheet.

FIG. 18 is a perspective view of one example of a parabolic trough solar collector and utilizing the sets of reflective aluminum composite sheets shown in FIG. 8, the collector being shown in a tilted position.

FIG. 19 is an end view of the parabolic trough solar collector shown in FIG. 18, the collector being shown in an alternate position.

FIG. 20 is a perspective view of an example frame structure utilized in the parabolic trough solar collector shown in FIGS. 18-19.

FIG. 21 is an end view of an alternate parabolic trough solar collector utilizing the sets of reflective aluminum composite sheets shown in FIG. 8.

FIG. 22 is a cross-section view taken along line 22-22 of FIG. 21.

FIG. 23 is an alternate perspective view of the parabolic dish solar collector shown in FIG. 11.

FIG. 24 is a top view of the dish utilized in the solar collector shown in FIG. 23.

FIG. 25 is a side view of the dish utilized in the solar collector shown in FIG. 23.

FIG. 26 is a cross-sectional view taken along the line 26-26 of FIG. 24.

FIG. 27 is an alternate perspective view of the cone-shaped reflective solar collector shown in FIG. 12.

FIG. 28 is a side view of the cone-shaped reflective solar collector.

FIG. 29 is a top view of the cone-shaped reflective solar collector.

FIG. 30 is an end view similar to FIG. 19 of an alternate parabolic trough solar collector.

FIG. 31 is an end view of the parabolic trough solar collector shown in FIG. 30, but pivoted to an alternate position

FIG. 32 is a perspective view of a photovoltaic (PV) solar collector with a reflective aluminum mirror composite sheet according to the invention.

FIG. 33 is an end view of the solar collector shown in FIG. 32.

While the invention is susceptible of various modifications and alternative constructions, certain embodiments are shown in the drawings and described in detail below. It should be understood, however, that there is no intention to limit the invention to the specific forms disclosed, but on the contrary, the intention is to cover all modifications, alternative constructions and methods, and equivalents falling within the spirit and scope of the invention.

### DETAILED DESCRIPTION OF THE INVENTION

FIG. 1 is an exploded perspective view of a mirror finish aluminum composite sheet 10 suitable for use in a solar collector in accordance with the invention.

The sheet (3 mm thickness) consists of top skin 12 which is a thin gauge aluminum sheet (0.50 mm to 0.30 mm thickness) that is polished, anodized, sputtering or bonded with a reflective film to produce a mirror finish over its entire top face 12a for facing the sun.

The middle layer 14 (2.20 mm to 2.4 mm thickness) is a core of low density polyethylene LDPE. Carbon fiber fibers or carbon fiber mesh may be embedded in the LDPE core as the core layer is formed. Embedding carbon fiber in the LDPE core enhances the strength of the core layer which results in increased strength for a given thickness core and thus permits reduction of the core thickness required to achieve a particular strength. In other words, embedding the carbon fiber into the LDPE core enables provision of a sheet that is lighter and stronger, and will be particularly useful for large-size sheets.

The bottom skin 16 is a second thin gauge aluminum sheet (0.50 mm to 0.30 mm thickness) that is coated or painted or anodized with matte black color over its entire bottom face 16a for facing away from the sun.

In the finished solar collector, the mirror finish top face 12a reflects or redirects solar energy to a target in the solar collector. In the finished solar collector, the black finish helps the absorption and radiation which keeps the back panel cool.

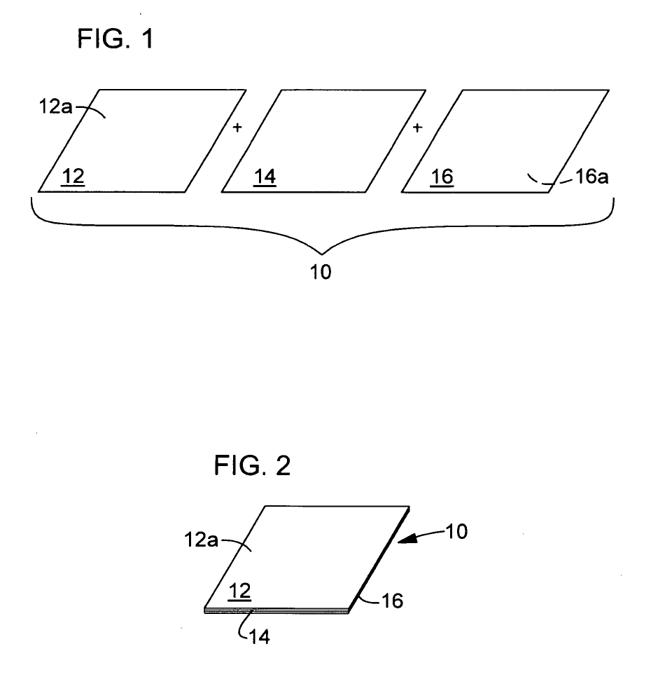

FIG. 2 is a perspective view of the mirror finish aluminum composite sheet 10 in its flat condition, ready for forming for use in a solar collector, with the top surface 12a being mirror finish aluminum, the middle core 14 being low density polyethylene, and the bottom surface 16a being black painted or otherwise coated aluminum. In one embodiment, the flat sheet 10 may be 60 inches long and 50.083 inches (4 feet, 2 and ½ inches) wide. The particular size of the composite sheet will depend on the solar collector design and application such as solar trough system, dish system, Fresnel system and solar cone system.

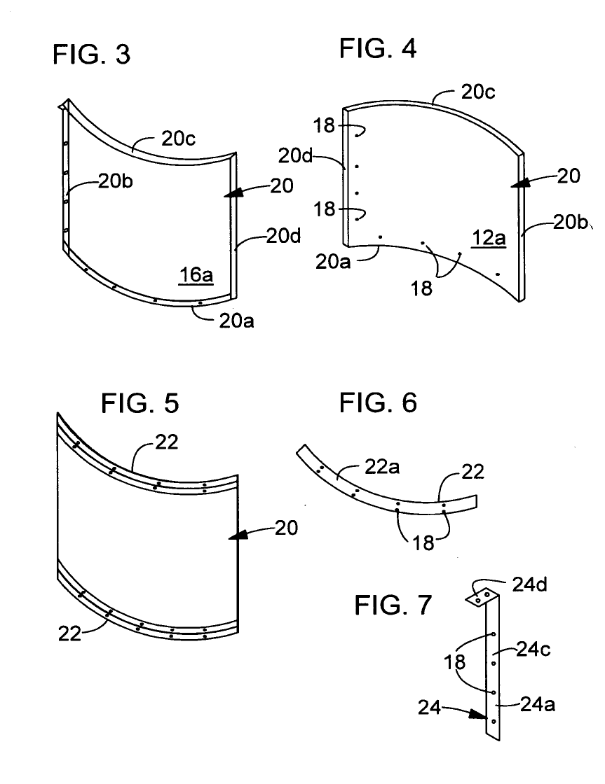

FIG. 3 is a perspective view of the back side 16a of the sheet 10 shown in FIG. 2 formed into a desired curvature. The curved sheet is designated as reference numeral 20. The back side 16a is coated black and formed with a convex curvature of either two or three dimensions.

A lateral curved joining stiffener 22 is riveted at spaced locations 18 along one of the curved edges 20a of the sheet 20, and a center straight joining stiffener 24 is riveted at spaced locations 18 along one of the straight edges 20b of the sheet 20.

FIG. 4 is a perspective view of the front side 12a of the formed sheet 20 shown in FIG. 3. The front side 12a has a mirror finish over its entire surface and is formed with a concave curvature of either two or three dimensions corresponding to the convex curvature of the back side and a constant thickness sheet. The sheets are curved as desired by passing through rollers utilizing a process similar to that used for curving a plain aluminum sheet.

FIG. 5 is a perspective view of the back side of the formed sheet 20 shown in FIG. 3 with lateral joining stiffeners 22 riveted along both curved edges 20a, 20c of the sheet, and ready for securing a second formed sheet 20 thereto both above and below the sheet 20 shown.

The curved sheets 20 are relatively rigid and will generally maintain their desired formed curvature. The curved stiffeners 22 are riveted along each of the curved edges 20a, 20c of the sheet 20 to help maintain the sheet in its formed curvature under all environmental considerations and installations and over long periods of time. The curved stiffeners 22 are preformed into a desired curvature, with the same center of curvature as the sheet 20 so that the front side 22a of the curved stiffener fits snugly on the back side of the curved edges 20a, 20c of the formed sheet 20. The stiffeners 22 are secured along their lengths to the curved edges 20a, 20c of the sheets 20 with rivets 18. The curved stiffeners 22 are made from the identical aluminum composite sheet material of the sheet 20 for identical thermal expansion characteristics between the sheets 20 and the stiffeners 22. This eliminates thermal expansion and contraction stresses that might otherwise develop at the riveted junctions of the sheets 20 and stiffeners 22 due to different thermal expansion rates of the sheets 20 and the stiffeners 22 if they were made from different materials.

The straight joining stiffeners 24 are each formed with two identical sides along its length for securing between two sheets 20. The joining stiffeners 24 are riveted along each of the straight edges 20b, 20b to help maintain the sheet in its formed condition under all environmental considerations and installations and over long periods of time. The main body 24c of the joining stiffener 24 is straight so that the front side 24a of the joining stiffener fits snugly on the back side of the straight edge 20b, 20d of the formed sheet 20. The stiffeners 24 are secured along their length to the straight edges 20b, 20d of the sheets with rivets 18. The joining stiffeners 24 are made from the identical aluminum composite sheet material of the sheet 20 for identical thermal expansion characteristics between the sheets 20 and the stiffeners 24. This eliminates thermal expansion and contraction stresses that might otherwise develop at the riveted junctions of the sheets 20 and stiffeners 22 due to different thermal expansion rates of the sheets 20 and the stiffeners 24 if they were made from different materials. The top angled end portion 24d of each joining stiffener 24 is used for securing the sheets to the supporting frame structure of the solar collector.

FIG. 6 is a perspective view of the curved lateral joining stiffener 22 made of the aluminum composite sheet material. As discussed above, the curved lateral joining stiffeners 22 or middle stiffeners 22, are preformed in the curved shaped for attaching between adjacent sheets.

FIG. 7 is a perspective view of the straight center joining stiffener 24 made of the aluminum composite sheet material. As discussed above, the straight center joining stiffener 24 are side stiffeners in an L with a main straight body 24c for attaching to the side of the sheets and an angled member 24d for securing the sheets to the supporting frame structure of the solar collector.

The back sides of the stiffeners 22, 24 are coated with black as the back sides of the sheets 20 so that the entire back side of joined sheets are black. As noted above, the stiffeners are made up of the same material as the reflective sheets so that the stiffeners and joiners will expand and contract at exactly the same thermal rate as the reflective sheets.

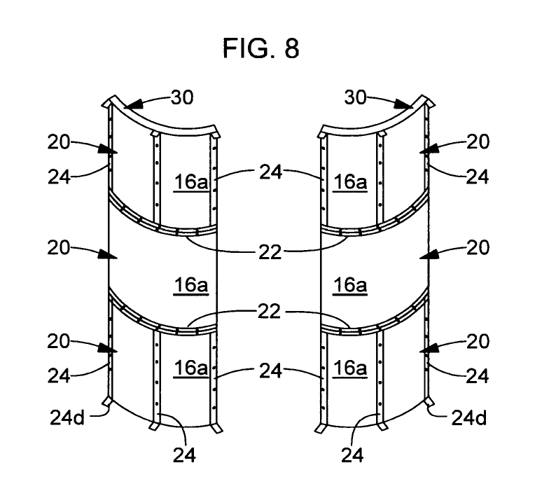

FIG. 8 is a back perspective view of six curved reflective sheets 20 joined together in two sets 30 of three sheets 20 each to establish opposite sides of a module in relative position to be joined together and/or secure to the frame support structure of a solar collector.

The back side of the sheets 20 are coated with black paint for facing away from the sun. The middle stiffeners 22 and the side stiffeners 24 are shown attached to the sheets. FIG. 8 also shows the way the side or end sheets are attached with a middle sheet. All attachment is accomplished with rivets.

The module shown includes six sheets 20. Three sheets are joined together with curved stiffeners 22 riveted in position on the back sides in a parabolic curvature to establish the left side of a parabola and the left side of the module. The other three sheets are similarly joined together with curved stiffeners 22 riveted in position on the back sides in a parabolic curvature to establish the right side of a parabola and the right side of the module. The sheets are all of the same size, such as the length and width noted above.

When installed into a solar collector, the outer and inner lengthwise edges 20b, 20d of the sheets 20 or module are secured lengthwise to a supporting framework.

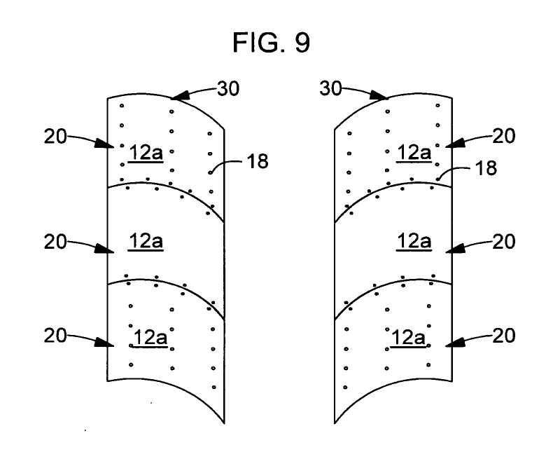

FIG. 9 is a front perspective view of the reflective aluminum composite sheets and module shown in FIG. 8, ready to be secured in position to the supporting frame of a solar collector. The front side of the sheets 20 have an aluminum mirror finish for facing away from the sun. The small heads of the rivets cover less than 1% of the total reflective front surface area to achieve high solar collector efficiency. The shape of the sheet is in a curved shaped. The light reflected from sun is focused on a target point or along a target line that is the focal point of the solar collector.

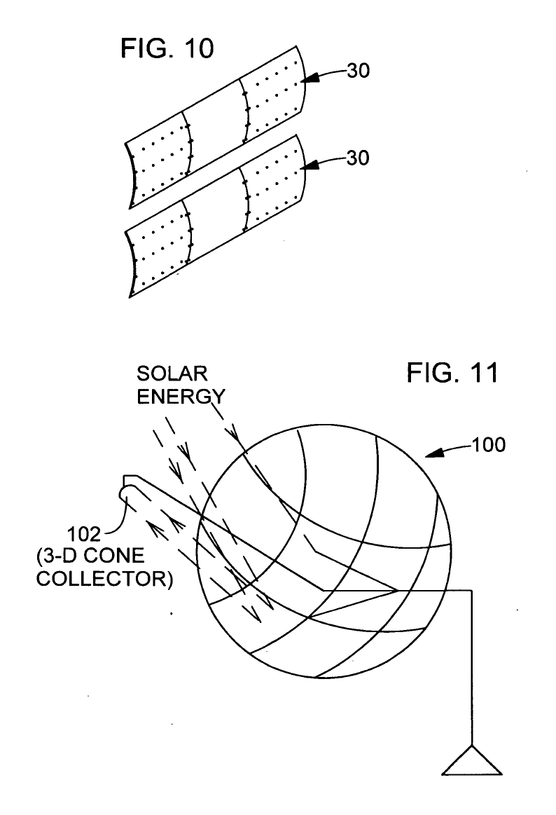

FIG. 10 is a perspective view of curved sheets connected together into modules for use in a parabola-shaped mirror solar collector, similar to the view thereof shown in FIG. 9.

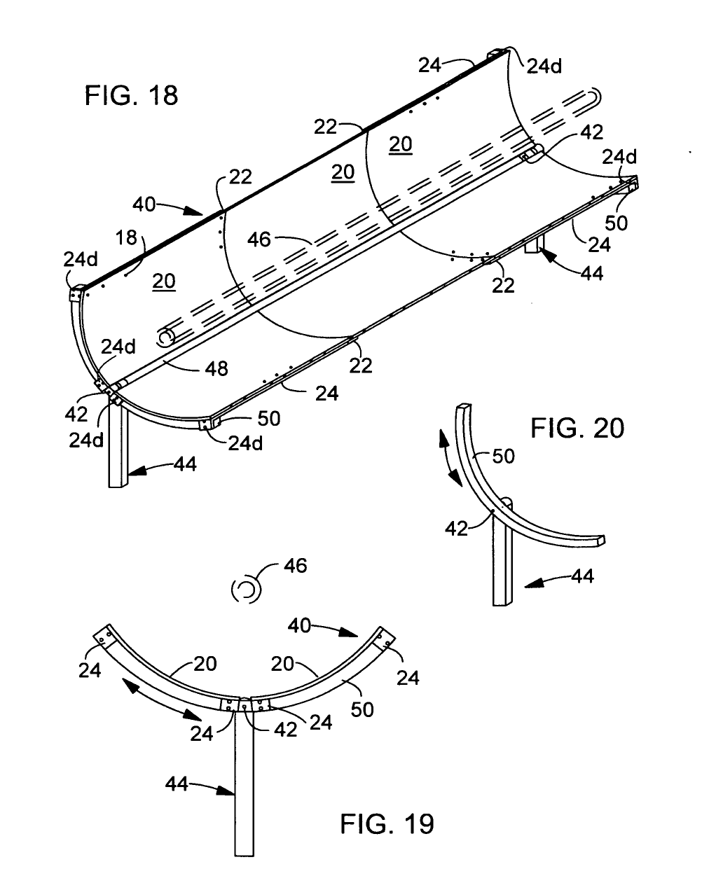

FIG. 18 is a perspective view of one example of a parabolic trough solar collector 40 and utilizing the sets of reflective mirror-finished aluminum composite sheets 20 shown in FIG. 8, the collector being shown in a tilted position.

The collector 40 includes the sets 30 of sheets pivotally supported at 42 on a supporting frame including post supports 44 and curved end supports 50 of the collector. The angled ends 24d of the supports 24 are secured to the curved end supports 50 as shown. The sheets 20 are cut and curved into the shape of a parabola as shown to collect the sun rays to be focused on the focal line, or absorption tube 46 (a.k.a. receiver tube) which is shown in dashed lines, but the support for which is not shown. Typically, multiple collectors 40 will be lined up end to end, and lines of collectors will be located together in a solar farm in a conventional manner. It is noted that as is conventional, there is an air gap 48 lengthwise along the center of the collector between the two halves of the collector.

FIG. 19 is an end view of the parabolic trough solar collector 40 shown in FIG. 18, the collector being shown pivoted to a horizontal position.

FIG. 20 is a perspective view of an example frame structure including post 44 and curved end supports 50 pivotally connected to the post as utilized in the parabolic trough solar collector shown in FIGS. 18-19.

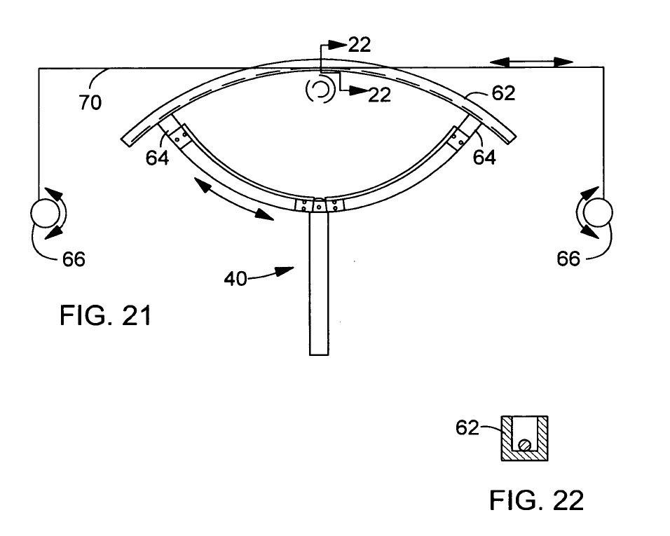

FIG. 21 is an end view of the parabolic trough solar collector 40 with one example drive arrangement for pivoting the reflective trough. In this instance, the drive includes a curved channel 62 connected at 64 to the ends of the reflective trough, a pulley 66 rotatably supported on each side of the channel, a pair of idler pulleys 68, a cable 70 that frictionally grips the inside of the channel, and bi-directional drive means connected to the pulleys to draw the cable in one direction or the other and thereby pivot the trough as desired. It is noted that although the cable is shown above the channel in FIG. 21 for illustrative purposes, the cable preferably tracks inside the entire length of the channel for maximum frictional grip.

FIG. 22 is a cross-section view of the channel 62 and cable 70 shown in FIG. 21.

Other pivot-drive arrangements may be utilized, and as is conventional, the drive will be controlled to track movement of the sun.

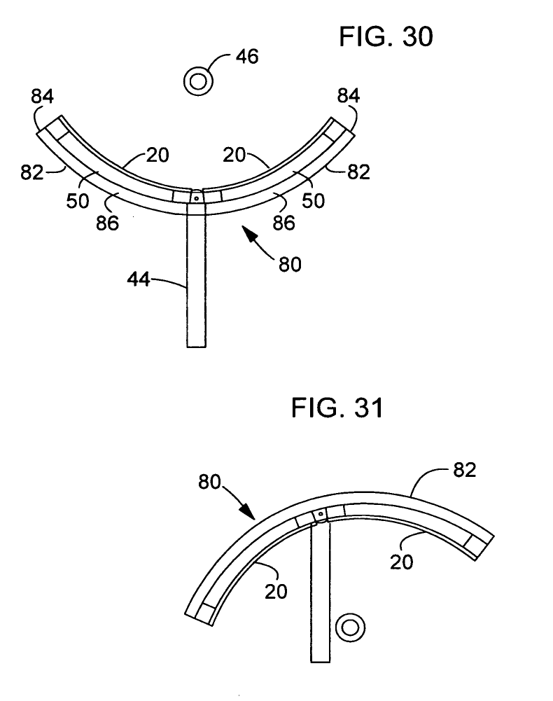

FIG. 30 is an end view an alternate parabolic trough solar collector 80.

Collector 80 is similar to collector 40, except that collector 80 further includes a sheet 82 of puncture proof plastic. Sheet 82 is connected, such as indicated at 84, to cover the entire back side of the reflector trough, to prevent hail from impinging on and damaging the reflective sheets 20 of the collector. As shown in FIG. 31, the parabolic trough may pivoted to a position with the reflective sheets under the plastic sheet 82, or in any other angular position to protect the sheets 20 from damage. An air gap 86 is provided between the plastic sheet 82 and the back side of the aluminum composite sheets 20.

FIG. 11 shows a dish shaped mirror finished aluminum composite sheet solar collector 100. The sheets are cut and curved into the shape of dish to collect the sun rays to be focused on the focal point 102 of the solar collector to collect maximum solar energy.

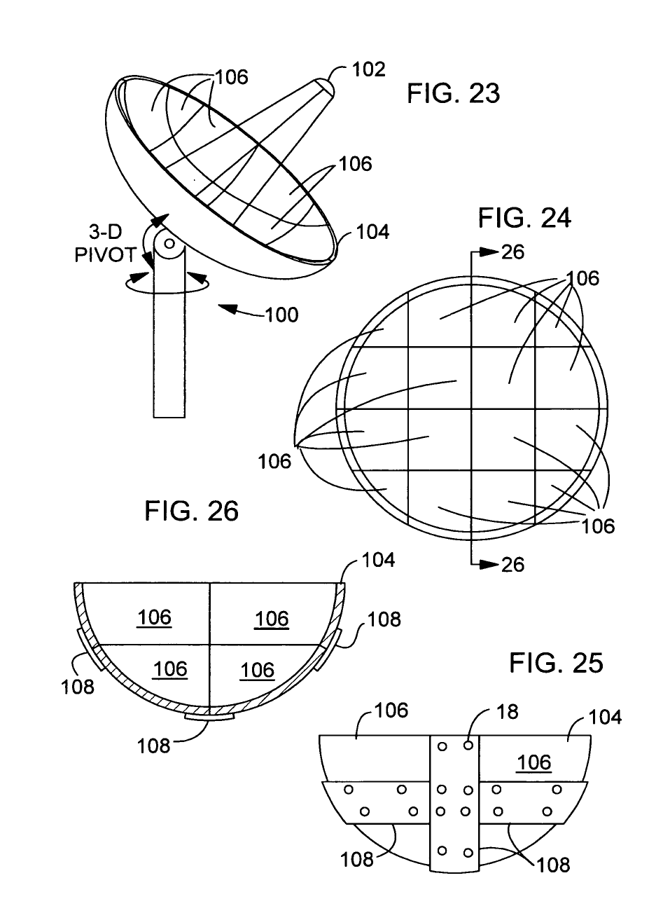

FIG. 23 is an alternate perspective view of the parabolic dish solar collector 100.

FIG. 24 is a top view of the dish 104 utilized in the solar collector 100, FIG. 25 is a side view of the dish 104, and FIG. 26 is a cross-sectional view the dish 104.

The dish 104 shown is constructed with 16 mirror finish aluminum composite sheets 10 described above, formed and cut into sheets indicated generally as sheets 106, and connected to establish a reflective parabolic dish shape. Thus, the sheets are formed with a 3-dimensional compound curvature. The sheet strip connectors 108 shown are similar to strip connectors 22 in that they are formed from the same aluminum composite sheet material as the sheets 10 themselves, and they are curved to overlap butt joints at the formed/cut sheets 106 for riveting 18 together. Alternately, for example, the dish may be constructed from 12 mirror finish aluminum composite sheets.

Advantageously, the solar dish collector 100 requires only a few reflective aluminum composite sheets as compared with prior solar dish collectors that require many glass-mirror reflectors.

Alternately, the dish 104 may be constructed with aluminum composite sheets that are cut and formed into identical pie-shaped wedges and then connected together with connector strips as indicated herein.

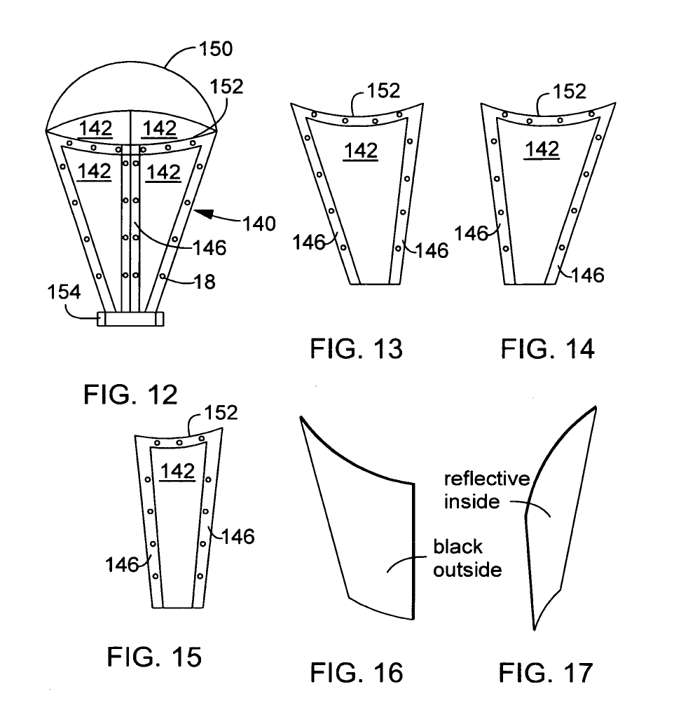

FIG. 12 shows a cone-shaped mirror finished aluminum composite sheet solar collector 140. FIG. 13-15 show three alternate perspective views of the reflective aluminum composite sheet 142, with connector strips 146 in place on the edge of the sheet. FIGS. 16-17 show two alternate perspective views of the reflective aluminum composite sheet 142, without the connector strips 146 on the edge of the sheet. FIG. 17 shows another alternate perspective view of the reflective aluminum composite sheet used in the cone-shaped solar collector, without the connector strips on the edge of the sheet.

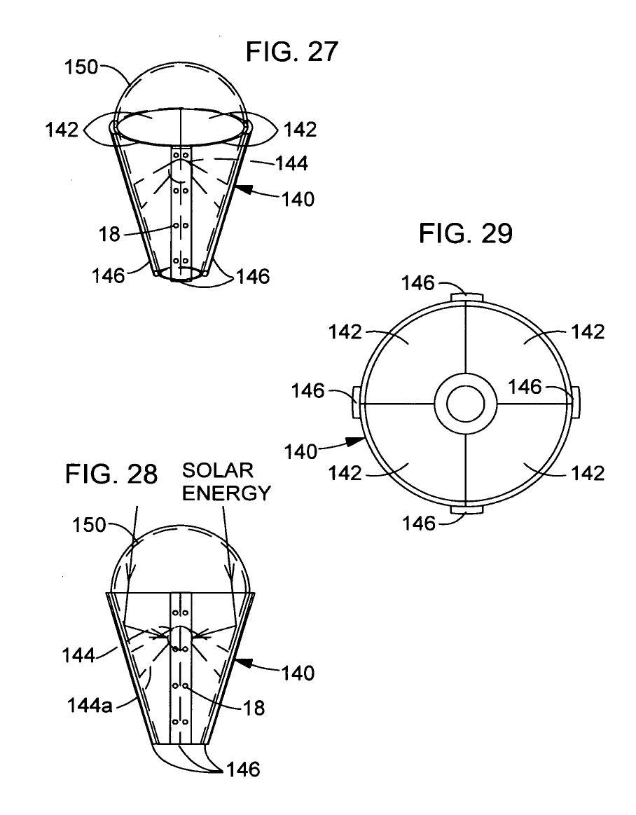

FIG. 27 is an alternate perspective view of the cone-shaped reflective solar collector 140, FIG. 28 is a side view of the collector 140, and FIG. 29 is a top view of collector 140.

The cone collector 140 is constructed with 4 identical mirror finish aluminum composite sheets 10 described above, formed and cut into sheets indicated generally as sheets 142, and connected to establish the reflective cone shape. In particular, the sheets 142 utilized are cut and curved into the shape of angularly one-fourth (90 degrees) frusto-conical shape to collect the sun rays to be focused on the focal point 144 of the solar collector to collect maximum solar energy. Thus, the sheets are formed with a 2-dimensional curvature. The focal point, or solar energy receiver/absorber unit is shown supported on frame 144a.

The sheet connectors 146 shown are similar to connectors 22 in that they are formed from the same aluminum composite sheet material as the sheets 10 themselves, and they are curved to overlap butt joints at the formed/cut sheets 142 for riveting 18 together.

Advantageously, the solar cone collector 140 requires only a few reflective aluminum composite sheets as compared with prior solar cone collectors that require many glass-mirror reflectors.

The cone collector 140 shown includes a transparent plastic dome cover 150, top encircling reinforcing ribs 152, and a base support 154. The dome cover permits control of the inside environment in the cone, such as to fill the cone with a particular gas or reduce the pressure inside the cone.

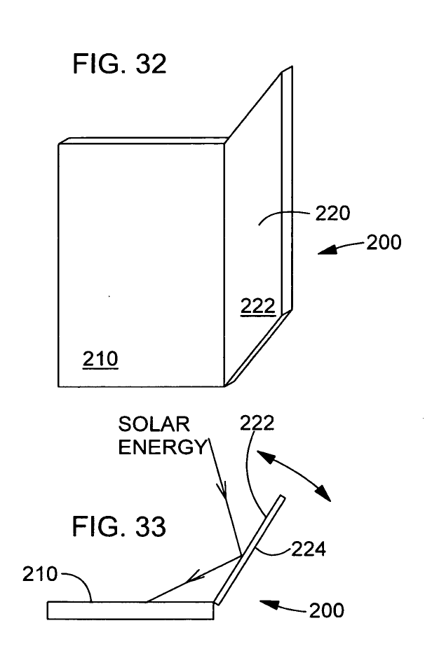

FIGS. 32 and 33 show a photovoltaic (PV) panel 210 and a reflective aluminum mirror composite sheet 220 of a PV solar collector (array) 200 for generating electrical power from solar energy. The array will conventionally include a number of aligned side-by-side PV panels. The PV panel will conventionally include one or more PV modules assembled into a pre-wired unit ready for installation into the array, with each module including multiple photovoltaic cells that convert the sunlight into direct current electricity sealed in an environmentally protective laminate. In this instance, each PV panel will be provided with a reflective aluminum mirror composite sheet. The aluminum composite sheet is generally as described above, including a mirror finish front surface 222 facing the PV panel for reflecting solar energy onto the panel. The aluminum composite sheet is preferably hinged or similarly mounted to the frame structure of the panel or to a frame structure with the panel for pivoting as indicated by the dashed curved arrow in FIG. 33 to an optimum angle in relation to the PV panel to reflect the solar energy (as indicated in dashed lines in FIG. 33) onto the panel and maximize the effects of focusing the solar energy onto the panel. The reflective mirror composite sheet may be coupled to a rotary drive and tracking system controller that can automatically pivot the sheet to track the movement of the sun as moves across the sky in order to maximize the reflection of solar energy onto the PV panel. The back side 224 of the reflective mirror composite sheet may be provided with a black finish as described above, and any stiffeners as may be used on the sheet may be made from the same composite sheet material as also described above.

The front surface 222 of the reflective mirror aluminum composite sheet 220 is uniquely modified with an anodized gold tint that is characterized as absorbing a high level of UV C, B and A range of solar spectrum of 200 nm to 340 nm (as compared with plain mirror finish), which blocks this spectrum from reaching the PV panel 210 to increase the life of the PV cells (it this spectrum of solar radiation that causes a significant portion of PV cell damage from aging and overheating), and concentrating increased solar wave length from 400 nm to 1100 nm onto the PV panel (as compared with plain mirror finish) which increases electrical production from the panel. From test results, the output of the PV panel 210 with a mirror finish gold tint is increased from about 30% to 60% due to this reduction in lower wave lengths and concentration of the higher wave lengths onto the panel. Advantageously, this also results in the reflective mirror aluminum composite sheet achieving a high hydrophobic effect, i.e., can become fully wetted at night, due to increased cooling of the sheet at night as compared with prior reflective sheets without the gold tint. This results in the gold-tint side of the sheet gathering increased amount of dew (as compared with prior reflective sheets without the gold tint) and achieving a self-cleaning capability as the collected dew on the fully wetted side runs of the sheet. This self-cleaning effect can be enhanced by rotating the sheet to a vertical (or substantially vertical) each morning (utilizing the tracking system) to “wash off” the surface and thereby extend the increased electrical production from the panel over long periods of time.

In production of the composite sheet 220, the top skin of layer of aluminum is produced in the continuous coil form with the anodized gold tint prior to the mechanical bonding process producing the composite sheet (as described above). The reflective aluminum composite sheet 220 with the gold-tinted surface achieves all of the features and advantages of the other aluminum composite sheets described herein.

The overall efficiency of a solar collector utilizing the aluminum composite sheets with a reflective mirror finish according to the invention is improved as compared with prior solar collectors because the sheets hold the formed shape and the reflective surface is not wavy and thus very flat or smoothly and/or continuously curved mirror finish only at the desired curvature, so that virtually all of the sun rays can be focused for collection of solar energy on the focal point (e.g. parabolic dish collector) or focal axis (e.g., parabolic trough collector) or focal plane (e.g., PV panel) of the solar collector. Such sheets are also easy to fabricate and easy to be installed which will reduce the capital cost and manpower involved, which in turn will result in energy production at a low rate.

Thus, significant advantages are achieved by use of reflective composite sheets according the invention, including an improvement in overall efficiency when compare to use of thin mirror aluminum sheets. Less number of bolts and supporting pipes are required to secure the reflective composite sheets in position, which reduces the cost in fabrication as well as reducing the amount of the reflective that is thereby obscured. The reflective composite sheets are flatter (i.e., with a smoother reflective surface) and more rigid when compare to thin mirror aluminum sheets. The reflective composite sheets are weather proof and easy to clean, and they hold shape better than thin mirror aluminum sheets. The reflective composite sheets require less time for installation, further reducing costs, when compare to installation of thin mirror aluminum sheets. As a result, the unit cost of producing energy is less when using the reflective composite sheets because of the improved efficiency and reduced costs in fabrication, installation, maintenance, and long life.

The modular construction of reflective composite solar collection sheets used in certain solar collectors enables provision and connection of any number of modules as desired in the installed solar collector.

The inherent stiffness and resistance to formation of surface “waviness” of the reflective aluminum composite sheets enables the installed solar collection surface to be smooth through connection of the sheets with only the joining stiffeners.

The construction of the reflective composite sheets enables use of a small number of fasteners along only the edges of the sheets, which results in un-obscured top surface area available for solar reflectivity of greater than 99 percent of the total surface area.

1. A solar collector comprising:
a) a frame;
b) a reflector connected to the frame; and
c) a target to receive solar radiation from the exposed mirror finish of reflector;
d) the reflector being characterized as comprising an aluminum composite sheet with first and second layers of aluminum sandwiching a solid thermoplastic core sheet, the first layer having an exposed mirror finish, and the second sheet having an exposed non-reflective finish facing opposite the mirror finish side of the first layer, the aluminum composite sheet being further characterized by the absence of significant surface waviness on the exposed mirror finish.

2. The solar collector as defined in claim 1 further comprising joining stiffeners joining two or more reflectors together, the joining stiffeners being constructed from the same aluminum composite sheet material as said reflectors.

3. The solar collector as defined in claim 2 wherein the reflector is formed as a segment of a reflective parabolic dish.

4. The solar collector as defined in claim 2 wherein the reflector is formed as a segment of a reflective parabolic trough.

5. The solar collector as defined in claim 4 wherein multiple reflectors are connected into identical modules establishing the parabolic trough.

6. The solar collector as defined in claim 4 further comprising means for pivoting the parabolic trough, and a plastic sheet covering the back side of the parabolic trough with an air gap established there-between for protection the back side of the parabolic trough from the weather.

7. The solar collector as defined in claim 2 wherein the reflector is formed as a segment of a reflective cone.

8. The solar collector as defined in claim 1 wherein the reflector is formed as flat sheet and the target comprises a PV panel to receive solar radiation from the reflector.

9. The solar collector as defined in claim 8 wherein the mirror finish side of the reflector includes a gold-tint characterized as absorbing a high level of UV C, B and A range of solar spectrum of 200 nm to 340 nm as compared with plain anodized mirror finish, and concentrating increased solar wave length from 400 nm to 1100 nm onto the PV panel as compared with plain anodized mirror finish.
